(19) United States
(12) Patent Application Publication
(10) Pub. No.: US 2026/0081453 A1
(43) Pub. Date: Mar. 19, 2026

(54) APPARATUS AND METHOD FOR CONTROLLING RECHARGING OF A BATTERY

(71) Applicant: SAMSUNG SDI CO., LTD., Yongin-si (KR)

(72) Inventors: Dongryul LEE, Yongin-si (KR); Junho JANG, Yongin-si (KR); Haemin KIM, Yongin-si (KR); Younghoon KO, Yongin-si, Gyeonggi-do (KR); Sangkoan YI, Yongin-si (KR); Yujin LEE, Yongin-si (KR); Youngwoong KWON, Yongin-si (KR)

(21) Appl. No.: 19/272,095

(22) Filed: Jul. 17, 2025

(30) Foreign Application Priority Data
Sep. 13, 2024 (KR) 10-2024-0126095

(51) Int. Cl. H02J 7/00; G01R 31/367; G01R 31/385; G01R 31/392

(52) U.S. Cl. CPC H02J 7/933; G01R 31/367; G01R 31/385; G01R 31/392; H02J 7/84

(57) ABSTRACT

The present disclosure relates to a method of controlling charging of a battery. The method includes generating electrode potential data based on a current profile and a voltage profile of a target battery, calculating a correlation between the electrode potential data and lifespan data of the target battery, predicting the lifespan of the target battery based on the correlation, and controlling a charging speed of the target battery based on the predicted lifespan of the target battery.

### CROSS-REFERENCE TO RELATED APPLICATION

This application claims priority under 35 U.S.C. § 119 to Korean Patent Application No. 10-2024-0126095, filed in the Korean Intellectual Property Office on Sep. 13, 2024, the entire contents of which are hereby incorporated by reference.

### BACKGROUND

### Field

The present disclosure relates to an apparatus and method for controlling charging of a battery.

### Description of the Related Art

A secondary battery refers to a battery that may be alternately charged and discharged. A secondary battery may convert chemical energy into electrical energy and discharge the energy. In a discharged state, the secondary battery may be recharged and store energy again in the form of chemical energy.

Such a secondary battery has the characteristic that when it is kept in a fully charged state, the deterioration of the battery is accelerated and the lifespan is shortened compared to when it is kept in a discharged state. That is, a secondary battery may have a problem that its lifespan is shortened depending on the charging capacity and the charging speed.

The above information disclosed in this Background section is for enhancement of understanding of the background of the present disclosure, and therefore, it may contain information that does not constitute related (or prior) art.

### SUMMARY

To address the above problem, an objective that the present disclosure provides an apparatus and method for controlling charging of a battery.

These and other aspects and features of the present disclosure will be described in or will be apparent from the following description of embodiments of the present disclosure.

In order to solve the technical problems above, a method of controlling charging of a battery in accordance with some embodiments of the present disclosure may include producing electrode potential data based on a current profile and a voltage profile of a target battery, calculating a correlation between the electrode potential data and lifespan data of the target battery, predicting a lifespan of the target battery based on the correlation, and controlling a charging speed of the target battery based on the predicted lifespan of the target battery.

According to some embodiments, the electrode potential data is produced by applying the current profile and the voltage profile to a physics-based model.

According to some embodiments, the physics-based model may include at least one of a Doyle-Fuller-Newman (DFN) model and a Single Particle Model (SPM).

According to some embodiments, producing electrode potential data may include calculating an integral value of the electrode potential based on a cut-off voltage of the target battery and the electrode potential data.

According to some embodiments, producing electrode potential data may further include calculating the correlation between the integral value of the electrode potential and the lifespan data of the target battery using a linear regression technique.

According to some embodiments, the correlation calculation may include calculating a correlation between the integral value of the electrode potential and a point in time when a charging capacity of the target battery suddenly drops, and increasing or decreasing the cut-off voltage based on the calculated correlation.

According to some embodiments, producing electrode potential data may further include recalculating the integral value of the electrode potential based on the changed cut-off voltage.

According to some embodiments, the correlation calculation may further include recalculating the correlation between the recalculated integral value of the electrode potential and the lifespan data of the target battery, and determining a final cut-off voltage by adjusting the cut-off voltage so that the recalculated correlation has linearity.

According to some embodiments, the predicting the lifespan of the target battery may include predicting a remaining lifespan (state of health, SOH) of the target battery over charge/discharge cycles based on a time of sudden drop.

According to some embodiments, the controlling a charging speed may include mapping the charging speed and the predicted remaining lifespan (SOH) of the target battery.

According to some embodiments, the controlling a charging speed may further include controlling the charging speed of the target battery based on the mapping.

In order to solve the technical problems above, a charging control device of a battery in accordance with some embodiments of the present disclosure may include at least one processor configured to read out and execute instructions stored in at least one memory to thereby cause the charging control device to function as: an electrode data production module configured to produce electrode potential data based on a current profile and a voltage profile of a target battery, a lifespan analysis module configured to calculate a correlation between the electrode potential data and lifespan data of the target battery, a lifespan prediction module configured to predict the lifespan of the target battery based on the correlation, and a charging control module configured to control a charging speed of the target battery based on the predicted lifespan of the target battery.

According to some embodiments, the electrode data production module may be configured to produce the electrode potential data by applying the current profile and the voltage profile to a physics-based model.

According to some embodiments, the electrode data production module may be configured to calculate an integral value of the electrode potential based on a cut-off voltage of the target battery and the electrode potential data.

According to some embodiments, the lifespan analysis module may be configured to calculate a correlation between the integral value of the electrode potential and a point in time when a charging capacity of the target battery suddenly drops.

According to some embodiments, the lifespan analysis module may be configured to increase or decrease the cut-off voltage based on the calculated correlation.

According to some embodiments, the lifespan analysis module may be configured to determine a final cut-off voltage by adjusting the cut-off voltage so that the correlation has linearity.

According to some embodiments, the lifespan prediction module may be configured to predict a remaining lifespan (state of health, SOH) of the target battery over charge/discharge cycles based on the point in time of sudden drop.

According to some embodiments, the charging control module may be configured to map the charging speed and the predicted remaining lifespan (SOH) of the target battery.

According to some embodiments, the charging control module may be configured to control the charging speed of the target battery based on the map.

According to some embodiments of the present disclosure, the lifespan of a battery may be predicted based on the correlation between electrode potential data and lifespan data of the battery.

According to some embodiments of the present disclosure, the remaining lifespan of a battery may be improved by controlling the charging speed of the battery based on the predicted lifespan of the battery.

However, aspects and features of the present disclosure are not limited to those described above, and other aspects and features not mentioned will be clearly understood by a person skilled in the art from the detailed description, described below.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 and FIG. 2 are block diagrams illustrating a charging control device of a battery according to some embodiments of the present disclosure.

FIG. 3 is a block diagram illustrating an information processing system used in the charging control device of a battery according to some embodiments of the present disclosure.

FIGS. 4A and 4B are examples illustrating the operation of the electrode data production module for a battery according to some embodiments of the present disclosure.

FIGS. 5A and 5B are examples illustrating the operation of the electrode data production module for a battery according to some embodiments of the present disclosure.

FIGS. 6 to 8 are examples illustrating the operation of the lifespan analysis module according to some embodiments of the present disclosure.

FIGS. 9 to 12 are examples illustrating the operation of the charging control module 180 according to some embodiments of the present disclosure.

FIG. 13 is a flowchart of a method of controlling charging of a battery according to some embodiments.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. §132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average. Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed”between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

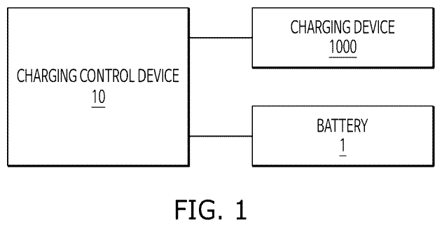

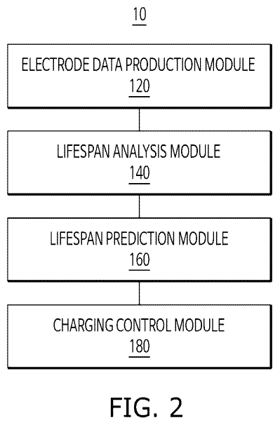

FIG. 1 and FIG. 2 are block diagrams illustrating a charging control device 10 of a battery according to some embodiments of the present disclosure.

With reference to FIG. 1, the charging control device 10 according to embodiments of the present disclosure may control the operation of a charging device 1000 to control the charging state of a battery 1. For example, the charging device 1000 may repeatedly charge and discharge on the battery 1 in response to a control signal received from the charging control device 10. In addition, the charging device 1000 may control the charging conditions (e.g., charging current/voltage, charging speed, charging capacity, or the like) of the battery 1 in response to a control signal received from the charging control device 10. The charging device 1000, which operates based on a control signal received from the charging control device 10, may change the deterioration pattern of the battery 10 by changing the charging conditions while charging the battery 1.

In an embodiment, the charging device 1000 may charge the battery 1 by applying a constant current (CC) and a constant voltage (CV). For example, when the charging voltage of the battery 1 is less than or equal to the reference voltage level (e.g., 4.4 V), the battery 1 may be charged by applying a constant current at a preset rate (e.g., 1.5 C-rate). Thereafter, when the voltage of the battery 1 reaches the reference voltage level, the charging device 1000 may charge the battery 1 by applying a voltage of the reference voltage level. Hence, the charging device 1000 fully charges the battery 1 by applying a voltage of the reference voltage level to the battery 1 (charging section). Thereafter, the charging device 1000 may gradually reduce the current applied to the battery 1 (resting section). Thereafter, when the voltage of the battery 1 reaches the charging cut-off voltage, the charging device 1000 may terminate charging of the battery 1. Here, the reference voltage level may be set based on the cut-off voltage. In addition, the cut-off voltage may indicate the charging upper limit voltage of the battery 1, but this is only an example and the present disclosure is not limited thereto. For example, the cutoff voltage may indicate the discharge end voltage of the battery 1. Further, the cutoff voltage may be appropriately adjusted depending on the charging conditions.

In an embodiment, the charging control device 10 may receive current profile and voltage profile data of the battery 1, which is repeatedly charged and discharged by the charging device 1000. The current profile may be data, for example, indicating the charging current applied to the battery 1 over time. The voltage profile may be data, for example indicating the charging voltage according to the charging capacity of the battery 1. However, the present disclosure is not limited to these examples.

The charging control device 10 may predict the lifespan of the battery 1 based on the received current profile and voltage profile data. The charging control device 10 may generate a control signal for controlling the charging device 1000 based on the predicted lifespan. Then, the charging control device 10 may transmit the control signal to the charging device 1000. The charging device 1000 may control the charging capacity of the battery 1 by controlling the charging speed of the battery 1 based on the control signal received from the charging control device 10. Thus, the charging device 1000 may extend the lifespan of the battery 1 by controlling the charging speed of the battery 1.

With reference to FIG. 2, the charging control device 10 of a battery according to some embodiments of the present disclosure may include an electrode data production module 120, a lifespan analysis module 140, a lifespan prediction module 160, and a charging control module 180.

In an embodiment, the electrode data production module 120 may produce electrode potential data based on the current profile and voltage profile of a target battery. For example, the electrode data production module 120 may apply the current profile and the voltage profile to a model that produces electrode potential data. The electrode data production module 120 may produce electrode potential data based on the output results of the model. Here, the model may include at least one of the Doyle-Fuller-Newman (DFN) model and the single particle model (SPM), which are physics-based models. But the present disclosure is not limited to these models. For example, the model may be various other types of models, such as an electrochemical model, a machine learning-based model, an adaptive filter-based model, or the like, all of which may be configured to produce electrode potential data based on a current profile and a voltage profile. Hence, the electrode data production module 120 may produce both positive electrode potential data and negative electrode potential data through the model. Here, the positive electrode potential data may represent the positive electrode potential according to the charging capacity of the target battery, and the negative electrode potential data may represent the negative electrode potential according to the charging capacity of the target battery.

In addition, the electrode data production module 120 may calculate the integral value of the electrode potential based on the cut-off voltage and electrode potential data of the target battery. Here, the integral value of the electrode potential may include the integral value of the negative electrode potential and the integral value of the positive electrode potential. For example, the electrode data production module 120 can calculate the integral value of the positive electrode potential from a graph representing the positive electrode potential according to the charging capacity, which may be referred to as a positive electrode V-Q graph. The electrode data production module 120 may calculate the integral value of the negative electrode potential from a graph representing the negative electrode potential according to the charging capacity, which may be referred to as negative electrode V-Q graph. For example, the electrode data production module 120 may calculate the area within the graph with a negative electrode V-Q curve as an upper limit (or boundary), and this area may be determined as the integral value of the negative electrode potential. Here, the starting range of the integration operation for calculating the integral value of the negative electrode potential may be the charging capacity at the cut-off voltage of the target battery. Preferably, the integration range may be from the charging capacity at the cut-off voltage of the target battery to the charge capacity when the negative electrode potential is 0 V. However, the present disclosure is not limited to these examples.

In an embodiment, the lifespan analysis module 140 may calculate a correlation between the electrode potential data and the lifespan of the target battery. For example, the lifespan analysis module 140 may calculate the correlation between at least one integral value among the integral value of the negative electrode potential and the integral value of the positive electrode potential produced by the electrode data production module 120 and the point in time when the charging capacity of the target battery suddenly drops. The correlation between the integral value of the negative electrode potential or the positive electrode potential and the point of sudden drop in the charging capacity may be calculated using a linear regression analysis technique (linear regression model). That is, the integral value of the negative electrode potential or the positive electrode potential be linear in correspondence to the point of sudden drop in the charging capacity. The lifespan analysis module 140 may produce a correlation having such linearity. Here, the point of sudden drop in charging capacity may indicate the cycle point at which the charging capacity of the target battery rapidly decreases due to rapid deterioration of the target battery.

In an embodiment, the lifespan analysis module 140 may calculate in advance a correlation according to linear regression analysis based on data about batteries with different charging conditions and/or types. Thereafter, the lifespan analysis module 140 may store the pre-calculated correlation and calculate the correlation between the electrode potential data and the lifespan of the target battery based on the stored correlation.

In addition, the lifespan analysis module 140 may increase or decrease the cut-off voltage based on the calculated correlation. For example, the lifespan analysis module 140 may adjust the cut-off voltage based on the linear determination coefficient (R-Square or R2) of the calculated correlation. Here, the linear determination coefficient (R2) evaluates the degree of linearity, and the determination coefficient may have a value of 0 to 1. The closer the linearity determination coefficient of the correlation between specific data sets is to 1, the higher the linearity of the distribution of corresponding data pairs may be. That is, the lifespan analysis module 140 may determine the final cut-off voltage by adjusting the cut-off voltage so that the correlation has linearity. In a specific example, the lifespan analysis module 140 may increase or decrease the cut-off voltage so that the linearity determination coefficient for the correlation between the integral value of the negative electrode potential and the point of sudden drop in the charging capacity of the target battery approaches 1. When the lifespan analysis module 140 adjusts the cut-off voltage, the area (i.e., integral value) of the negative electrode V-Q curve may change. Thus, when the electrode data production module 120 receives the adjusted cut-off voltage, the electrode data production module 120 may recalculate the integral value of the negative electrode potential. Thereafter, the electrode data production module 120 may transfer the recalculated integral value of the negative electrode potential to the lifespan analysis module 140, and the lifespan analysis module 140 may calculate the linearity determination coefficient for the correlation between the recalculated integral value of the negative electrode potential and the point of sudden drop in the charging capacity. By repeating this process, the lifespan analysis module 140 and the electrode data production module 120 may determine the cut-off voltage value, i.e., the final cut-off voltage, having the highest linearity with respect to the correlation between the integral value of the negative electrode potential and the point of sudden drop in the charging capacity.

In an embodiment, the lifespan prediction module 160 may predict the lifespan of the target battery based on the correlation received from the lifespan analysis module 140. For example, the lifespan prediction module 160 may receive the correlation between the final cut-off voltage and the point of sudden drop in the charging capacity from the lifespan analysis module 140. Thereafter, the lifespan prediction module 160 may predict the remaining lifespan (SOH) over charge/discharge cycles of the target battery based on the correlation. For example, since there is a proportional relationship between the retardation (or extension) of the point in time of sudden drop in the charging capacity and an increase in the remaining lifespan (SOH) of the battery, the remaining lifespan (SOH) may be predicted based on the point in time of sudden drop.

In an embodiment, the charging control module 180 may control the charging speed of the target battery based on the predicted lifespan of the target battery received from the lifespan prediction module 160. For example, the charging control module 180 may map in advance the charging speed of the target battery and the corresponding remaining lifespan (SOH) of the target battery. Here, there may be a trade-off between the charging speed and the remaining lifespan (SOH) of the target battery. That is, if the charging speed is fast, the battery lifespan may be shortened due to a chemical reaction inside the battery. On the other hand, a slower charging speed may generally increase the battery's lifespan, but other factors, such as an increase in the number of times the battery is charged and discharged, may shorten the battery's lifespan. The charging control module 180 may determine an appropriate charging speed so as to maintain the predicted remaining lifespan (SOH) of the target battery based on such a trade-off relationship or mapping relationship. For example, the charging control module 180 may receive charging speed data and predicted remaining lifespan data of the battery from at least one of the electrode data production module 120, the lifespan analysis module 140, and the lifespan prediction module 160. In a specific example, the charging control module 180 may receive charging speed data for the first cut-off voltage according to a first charging condition and data on the remaining lifespan (SOH) of the target battery according to the first cut-off voltage. In addition, the charging control module 180 may receive charging speed data for the second cut-off voltage according to a second charging condition and data on the remaining lifespan (SOH) of the target battery according to the second cut-off voltage. Here, the first charging condition and the second charging condition may be different charging conditions applied to the same target battery. The charging control module 180 may calculate the optimal charging speed of the target battery based on the result of mapping the remaining lifespan (SOH) and the charging speed according to the first cut-off voltage and the second cut-off voltage. Hence, the charging control module 180 may control the charging device to charge the target battery at an optimal charging speed. Here, the charging control module 180 may generate a control signal so that the charging device increases or decreases the charging speed of the target battery. Then, the charging control module 180 may transfer the control signal to the charging device.

As described above, the charging control device 10 of a battery according to some embodiments of the present disclosure may predict the lifespan of the battery based on the correlation between the electrode potential data and the lifespan of the battery. And according to some embodiments of the present disclosure, the remaining lifespan of the battery may be improved by the charging control device 10 that controls the charging speed of the battery based on the predicted lifespan of the battery.

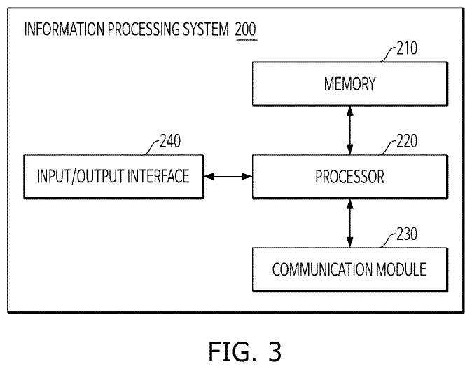

FIG. 3 is a block diagram illustrating an information processing system 200 used in the charging control device 10 of a battery according to some embodiments of the present disclosure.

Referring to FIG. 3, the information processing system 200 that may correspond to the charging control device 10 of a battery illustrated in FIG. 1. The information processing system 200 may include a memory 210, a processor 220, a communication module 230, and an input/output interface 240. As shown in FIG. 2, the information processing system 200 may be configured to communicate information and/or data through a network by using the communication module 230. In an embodiment, the information processing system 200 may include at least one of the memory 210, the processor 220, the communication module 230, and the input/output interface 240.

The memory 210 may include any non-transitory computer-readable recording medium. In an embodiment, the memory 210 may include a permanent mass storage device such as read only memory (ROM), disk drive, solid state drive (SSD), or flash memory. As another example, a permanent mass storage device such as ROM, SSD, flash memory, or disk drive may be included in the information processing system 200 as a separate permanent storage device that is distinct from the memory 210. In addition, the memory 210 may store software components including an operating system and at least one program code. For example, the code may implement the electrode data production module, the lifespan analysis module, the lifespan prediction module, the charging control module, or the like that are installed and operated in the information processing system 200.

These software components may be loaded from a computer-readable recording medium that is separate from the memory 210. This separate computer-readable recording medium may include a recording medium directly connectable to the information processing system 200, and may include, for example, a computer-readable recording medium such as floppy drive, disk, tape, DVD/CD-ROM drive, or memory card. As another example, software components may be loaded onto the memory 210 through the communication module 230 other than a computer-readable recording medium. For example, at least one program may be loaded onto the memory 210 based on a computer program (e.g., programs for implementing the electrode data production module, the lifespan analysis module, the lifespan prediction module, the charging control modules, or the like) installed by files provided over the communication module 230 by developers or a file distribution system that distributes installation files for applications.

The processor 220 may be configured to process instructions of a computer program by performing basic arithmetic, logic, and input/output operations. The instructions may be provided by the memory 210 to a user terminal (not shown) or another external system through the communication module 230. For example, the processor 220 may collect lifespan evaluation data (e.g., current and voltage profiles) of a target battery from one or more manufacturing facilities, produce electrode potential data based on the lifespan evaluation data, calculate a correlation between the electrode potential data and the lifespan of the target battery, predict the lifespan of the target battery based on the correlation, and control the charging speed of the target battery based on the predicted lifespan.

The communication module 230 may provide a configuration or function for the user terminal (not shown) and the information processing system 200 to communicate with each other through a network. In some embodiments, the communication module 230 may provide a configuration or function for the information processing system 200 to communicate with an external system such as a separate cloud system. In an embodiment, a control signal, command or data provided under the control of the processor 220 of the information processing system 200 may be transmitted through the communication module 230 over the network and received by the user terminal and/or external system via the communication modules of the user terminal and/or external system. For example, the prediction data and control signals generated by the information processing system 200 may be transmitted through the communication module 230 over a network to the user terminal and/or external system via the communication modules of the user terminal and/or external system. Additionally, the user terminal and/or external system having received information on the predicted lifespan and/or charging speed control of the target battery may output the received information through display devices.

The input/output interface 240 of the information processing system 200 may be a means for interfacing with a device (not shown) for input or output that can be connected to or included in the information processing system 200. In FIG. 2, the input/output interface 240 is shown as a separate component from the processor 220, but without being limited thereto, the input/output interface 240 may be configured to be included in the processor 220. The information processing system 200 may include more components than those shown in FIG. 2. However, there is no need to explicitly illustrate most of the related art components.

The processor 220 of the information processing system 200 may be configured to manage, process, and/or store information and/or data received from a plurality of user terminals and/or a plurality of external systems. According to an embodiment, the processor 220 may receive battery lifespan data, charging data, or the like from a user terminal and/or an external system. The processor 220 may predict the lifespan of the target battery based on electrode potential data and generate a control signal for controlling the charging speed based on the result of mapping the predicted lifespan and the charging speed. The processor 220 may output the signal to a display device connected to the information processing system 200.

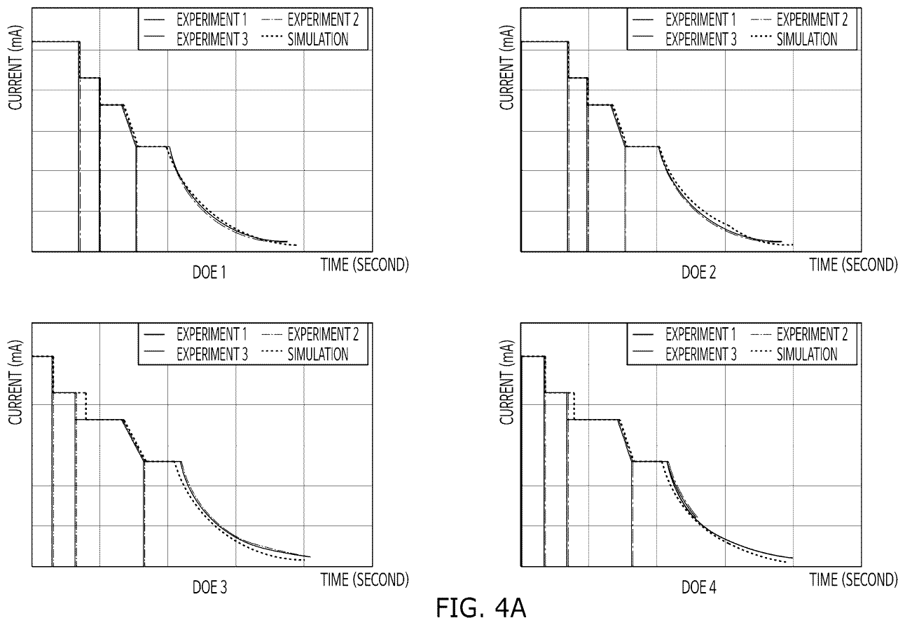

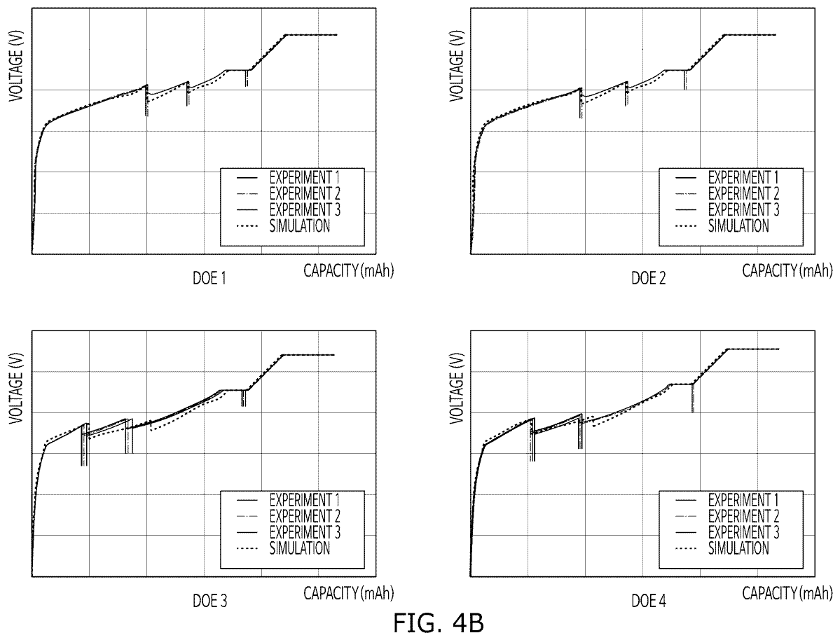

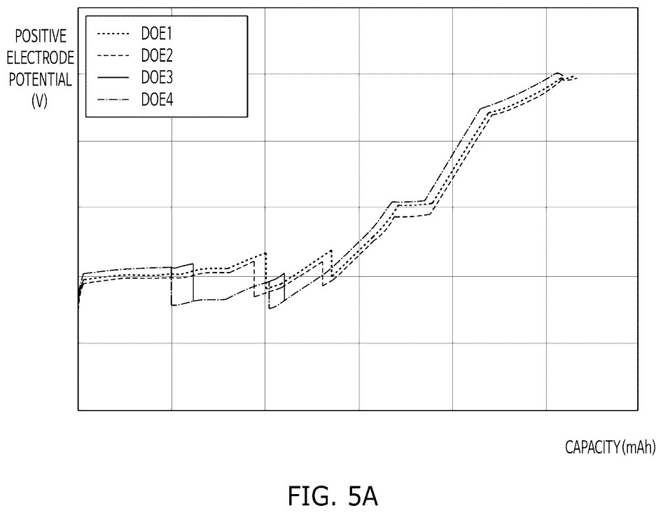

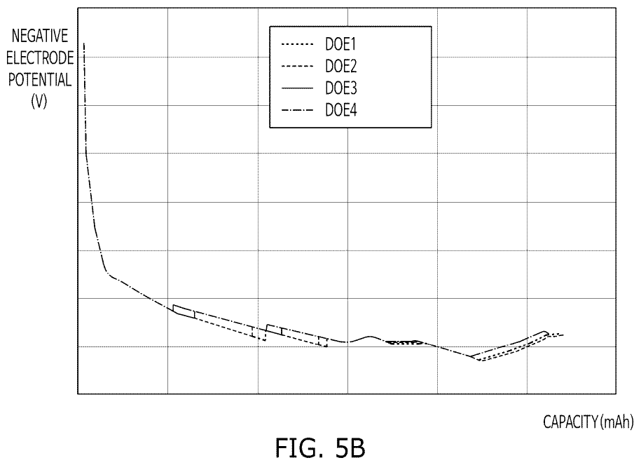

FIGS. 4A and 4B and FIGS. 5A and 5B are examples illustrating the operation of the electrode data production module 120 for a battery according to some embodiments of the present disclosure.

Referring to FIGS. 4A and 4B, the electrode data production module 120 may apply the current profile data illustrated in FIG. 4A and the voltage profile data illustrated in FIG. 4B to a physics-based model. The voltage profile data and current profile data shown are examples of data obtained from four experiments (DOE1 to DOE4). Here, the four experimental designs refer to experiments or simulations that vary the charging conditions of the battery, and the charging conditions may indicate conditions of a constant current and/or a constant voltage applied to the battery. Additionally, the model may be a physics-based model that estimates negative electrode potential data or positive electrode potential data based on the current profile and voltage profile. In specific examples, the model may include at least one of a Doyle-Fuller-Newman (DFN) model and a single particle model (SPM). But the present disclosure is not limited to these examples.

As shown in FIG. 4A, the current profile may represent the charging current over time. Meanwhile, as shown in FIG. 4B, the voltage profile may represent the charging voltage according to the charging capacity.

Referring to FIGS. 5A and 5B, the electrode data production module 120 may apply the voltage profile data and current profile data shown in FIGS. 4A and 4B to the physics-based model to produce the negative electrode potential data shown in FIG. 5A and the positive electrode potential data shown in FIG. 5B. Here, the positive electrode potential data may be data representing the positive electrode potential according to the charging capacity of each battery. The negative electrode potential data may be data representing the negative electrode potential according to the charging capacity of each battery.

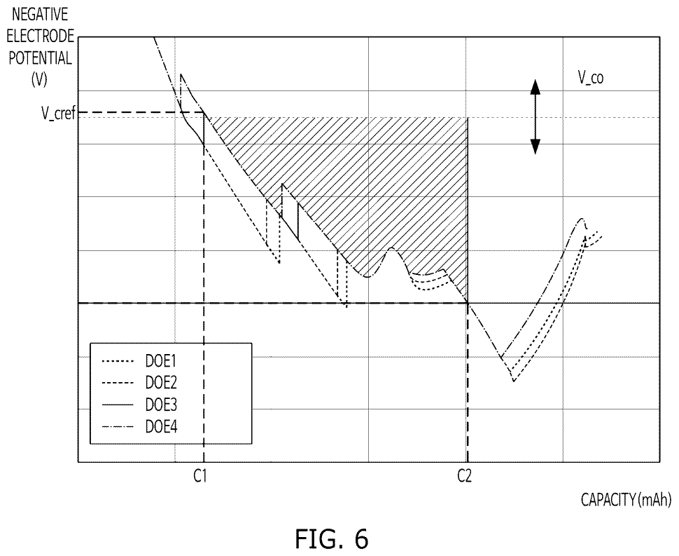

FIGS. 6 to 8 are examples illustrating the operation of the lifespan analysis module 140 according to some embodiments of the present disclosure.

Referring to FIG. 6, the lifespan analysis module 140 may receive negative electrode potential data and the integral value of the negative electrode potential from the electrode data production module 120. The lifespan analysis module 140 may calculate the correlation between the received integral value of the negative electrode potential and the point in time of sudden drop.

In an embodiment, the lifespan analysis module 140 may increase or decrease the cut-off voltage V_co based on the calculated correlation. Here, the negative electrode potential data is produced by inputting the voltage profile and current profile generated by the four experiments (DOE1 to DOE4) shown in FIGS. 4A and 4B into the physics-based model.

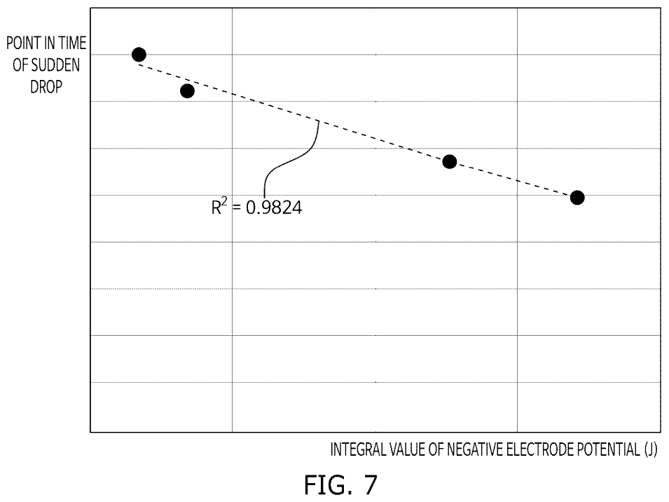

The electrode data production module 120 may calculate the integral value of the negative electrode potential from a graph representing the negative potential according to the charging capacity (i.e., negative electrode V-Q graph). As shown in FIG. 6, the electrode data production module 120 may calculate the area of the negative electrode V-Q curve, and this area may correspond to the integral value of the negative electrode potential. The integration range for the negative electrode potential may be from the charging capacity C1 at the cut-off voltage of the battery (i.e., when the negative electrode potential is V_cref (e.g., 0.07 V)) to the charging capacity C2 when the negative electrode potential is 0 V. However, the present disclosure is not limited thereto. Referring to FIG. 7, the integral value of the negative electrode potential may have linearity in correspondence to the point in time of sudden drop, and the lifespan analysis module 140 may calculate a correlation having such linearity. In an embodiment, the lifespan analysis module 140 may calculate in advance a correlation according to linear regression analysis based on data of batteries with different charging conditions and/or types. Thereafter, the lifespan analysis module 140 may store the pre-calculated correlation and calculate the correlation between the electrode potential data and the lifespan of the target battery based on the stored correlation.

In addition, the lifespan analysis module 140 may adjust the cut-off voltage V_co so that the correlation has linearity as shown in FIG. 6. When the lifespan analysis module 140 adjusts the cut-off voltage, the area of the negative electrode V-Q curve may change. Hence, when the electrode data production module 120 receives the adjusted cut-off voltage, the electrode data production module 120 may recalculate the integral value of the negative electrode potential. Thereafter, the electrode data production module 120 may transfer the recalculated integral value of the negative electrode potential to the lifespan analysis module 140, and the lifespan analysis module 140 may calculate the linearity determination coefficient for the correlation between the recalculated integral value of the negative electrode potential and the point in time of sudden drop in the charging capacity. By repeating such a process, the lifespan analysis module 140 and the electrode data production module 120 may determine the cut-off voltage value V_co, i.e., the final cut-off voltage, having the highest linearity with respect to the correlation between the integral value of the negative electrode potential and the point in time of sudden drop in the charging capacity. For example, the lifespan analysis module 140 may determine the final cut-off voltage so that the square of R (R2), which is the coefficient of determination of the correlation, has the largest value. Here, the coefficient of determination of the correlation may have a value of 0 to 1.

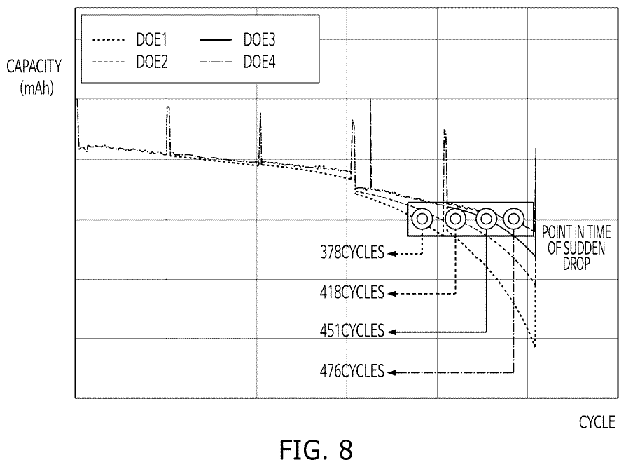

Referring to FIG. 8, the lifespan prediction module 160 may predict the lifespan of the target battery based on the correlation received from the lifespan analysis module 140. For example, the lifespan prediction module 160 may receive the correlation between the final cut-off voltage and the point in time of sudden drop in the charging capacity from the lifespan analysis module 140. Thereafter, the lifespan prediction module 160 may predict the remaining lifespan (SOH) of the target battery over the charge/discharge cycles based on the correlation. As illustrated in FIG. 8, the lifespan prediction module 160 may predict the remaining lifespan (SOH) of the target battery over the charge/discharge cycles for the four experiments (DOE1 to DOE4) based on the points in time of sudden drop (e.g., 378 cycles, 418 cycles, 451 cycles, 476 cycles).

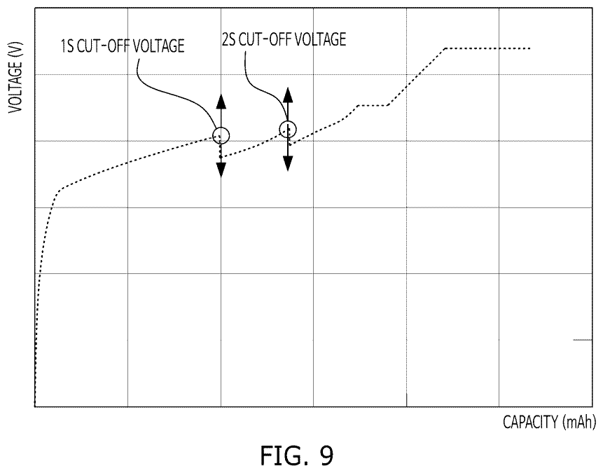

FIGS. 9 to 12 are examples illustrating the operation of the charging control module 180 according to embodiments of the present disclosure.

Referring to FIG. 9, the charging control module 180 may receive the charging speed data and the predicted remaining lifespan data of the target battery from at least one module among the electrode data production module 120, the lifespan analysis module 140, and the lifespan prediction module 160. In a specific example, the charging control module 180 may receive data on the charging speed for a 1S cut-off voltage according to the first-stage charging condition and data on the remaining lifespan (SOH) of the target battery according to the 1S cut-off voltage. Additionally, the charging control module 180 may receive data on the charging speed for a 2S cut-off voltage according to the second-stage charging condition and data on the remaining lifespan (SOH) of the target battery according to the 2S cut-off voltage. Here, the first-stage charging condition and the second-stage charging condition may be different charging conditions applied to the same target battery.

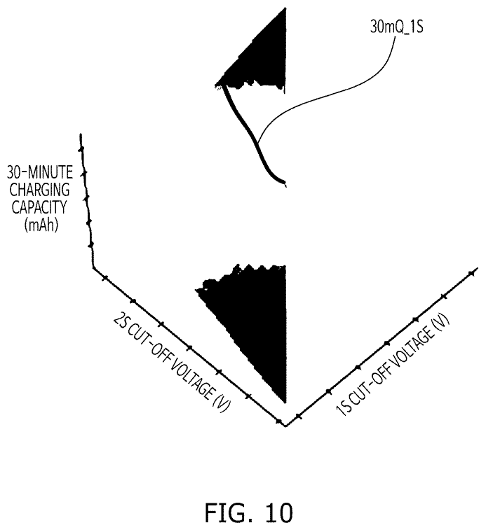

Referring to FIGS. 10 to 12, the charging control module 180 may map the charging speed of the target battery and the remaining lifespan (SOH) of the target battery in advance. For example, the charging control module 180 may store in advance result data that maps the charging speed and charging capacity of the target battery. Additionally, the charging control module 180 may receive predicted lifespan data from the lifespan prediction module 160 and map it and the charging speed according to the point in time of sudden drop (or remaining lifespan (SOH)). Hence, the charging control module 180 may control the charging speed of the target battery based on the mapping results.

As a specific example, assume that the final cut-off voltage determined under the first-stage charging condition (1S) is 4.14 V. The charging control module 180 may control the charging speed of the target battery to be fast or slow under the second-stage charging condition (2S) based on the final cut-off voltage of 4.14 V in the first-stage charging condition (1S) and the mapping result. That is, the charging control module 180 may control the charging speed of the target battery to be fast or slow so that the remaining lifespan of the target battery is extended or maintained under the second-stage charging condition (2S) based on the remaining lifespan of the target battery predicted under the first-stage charging condition (1S).

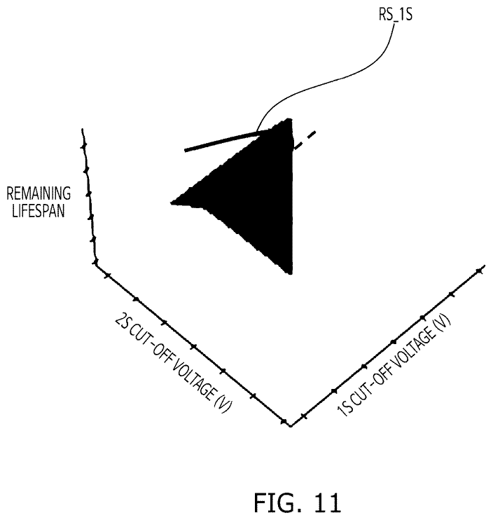

In an embodiment, the charging control module 180 may map the capacity for 30-minute charging according to the first cut-off voltage (1S) and the second cut-off voltage (2S) as shown in FIG. 10. Here, the capacity change for 30-minute charging means the charging speed. That is, the charging control module 180 may produce a charging speed curve (30mQ_1S) for the first final cut-off voltage (4.14V) according to the mapping result. As shown in FIG. 11, the charging control module 180 may map the remaining lifespan (SOH) according to the first cut-off voltage (1S) and the second cut-off voltage (2S). That is, the charging control module 180 may produce a curve (RS_1S) of the predicted remaining lifespan for the first final cut-off voltage (4.14 V) based on the mapping result.

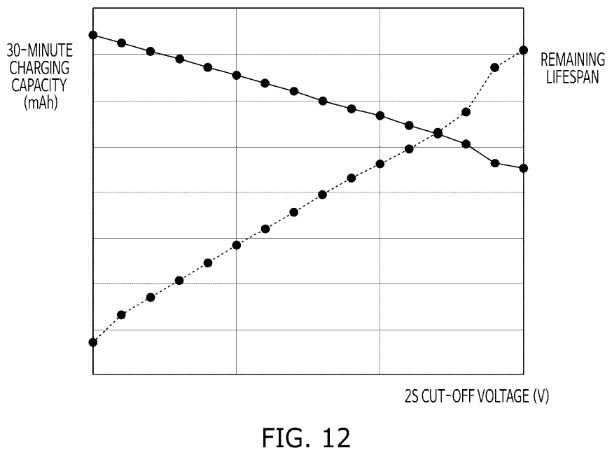

As shown in FIG. 12, based on the mapping result described above, the charging control module 180 may estimate the second cut-off voltage (2S) to maintain the predicted remaining lifespan (SOH) of the target battery, and, at the same time, map an appropriate charging speed of the target battery. By repeating the above-described process, the charging control module 180 may produce the optimal charging speed of the target battery based on the result of mapping the remaining lifespan (SOH) according to the first cut-off voltage and the second cut-off voltage and the charging speed. Hence, the charging control module 180 may control charging at an optimal charging speed. Thus, the charging control module 180 may thereby control the charging speed of the target battery to maintain or extend the remaining lifespan of the target battery.

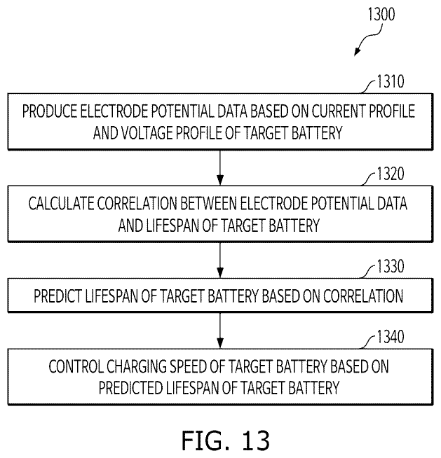

FIG. 13 is a flowchart of a method 1300 of controlling charging of a battery according to some embodiments.

Referring to FIG. 13, the charging control method 1300 may be executed by the charging control device 10 of FIG. 1 and FIG. 2.

The charging control method 1300 may be initiated with a step of producing electrode potential data based on the current profile and voltage profile of the target battery (1310). For example, the electrode data production module 120 in FIG. 2 may produce electrode potential data based on the current profile and voltage profile of the target battery.

According to an embodiment, in the step of producing electrode potential data (1310), the current profile and the voltage profile may be applied to a model for predicting the battery remaining lifespan (SOH). Thereafter, in the step of producing electrode potential data (1310), the electrode potential data may be generated by the model. Additionally, in the step of producing electrode potential data (1310), the integral value of the negative electrode potential and the integral value of the positive electrode potential may be generated based on the electrode potential data.

In addition, a correlation between electrode potential data and the lifespan of the target battery may be calculated (1320). For example, the lifespan analysis module 140 in FIG. 2 may calculate the correlation between electrode potential data and the lifespan of the target battery.

In the step of calculating the correlation (1320), a correlation between at least one integral value among the integral value of the negative electrode potential and the integral value of the positive electrode potential and the point in time when the charging capacity of the target battery suddenly drops may be calculated. Thereafter, in the step of calculating the correlation (1320), the cut-off voltage may be increased or decreased based on the correlation. In the step of calculating the correlation (1320), the final cut-off voltage may be determined while the cut-off voltage is adjusted so that the correlation has linearity.

Finally, the lifespan of the target battery may be predicted based on the correlation (1330). For example, the lifespan prediction module 160 in FIG. 2 may predict the lifespan of the target battery based on the correlation.

In an embodiment, in the step of predicting the lifespan of the target battery (1330), the remaining lifespan (SOH) of the target battery over charge/discharge cycles may be predicted based on the point in time of sudden drop.

Additionally, the charging speed of the target battery may be controlled based on the predicted lifespan of the target battery (1340). For example, the charging control module 180 in FIG. 2 may control the charging speed of the target battery based on the predicted lifespan of the target battery.

In an embodiment, in the step of controlling the charging speed (1340), the charging speed of the target battery and the remaining lifespan (SOH) of the target battery may be mapped, and the charging speed of the target battery may be controlled based on the cut-off voltage and the mapping result.

As described above, according to some embodiments of the present disclosure, the lifespan of the battery may be predicted based on the correlation between the electrode potential data and lifespan data of the battery. In addition, the remaining lifespan of the battery may be improved by controlling the charging speed of the battery based on the predicted lifespan of the battery.

Although the present disclosure has been described with reference to embodiments and drawings illustrating aspects thereof, the present disclosure is not limited thereto. Various modifications and variations can be made by a person skilled in the art to which the present disclosure belongs.

### DESCRIPTION OF SOME REFERENCE SYMBOLS

1: battery
10: charging control device
120: electrode data production module
140: lifespan analysis module
160: lifespan prediction module
180: charging control module
200: information processing system
210: memory
220: processor
230: communication module
240: input/output interface
1000: charging device

What is claimed is:

1. A method of controlling charging of a battery, the method comprising:
producing electrode potential data based on a current profile and a voltage profile of a target battery;
calculating a correlation between the electrode potential data and lifespan data of the target battery;
predicting a lifespan of the target battery based on the correlation; and
controlling a charging speed of the target battery based on the predicted lifespan of the target battery.

2. The charging control method as claimed in claim 1, wherein the electrode potential data is produced by applying the current profile and the voltage profile to a physics-based model.

3. The charging control method as claimed in claim 2, wherein the physics-based model comprises at least one of a Doyle-Fuller-Newman (DFN) model and a Single Particle Model (SPM).

4. The charging control method as claimed in claim 3, wherein producing electrode potential data comprises calculating an integral value of the electrode potential based on a cut-off voltage of the target battery and the electrode potential data.

5. The charging control method as claimed in claim 4, wherein producing electrode potential data further comprises calculating the correlation between the integral value of the electrode potential and the lifespan data of the target battery using a linear regression technique.

6. The charging control method as claimed in claim 5, wherein the correlation calculation comprises:
calculating a correlation between the integral value of the electrode potential and a point in time when a charging capacity of the target battery suddenly drops; and
increasing or decreasing the cut-off voltage based on the calculated correlation.

7. The charging control method as claimed in claim 6, wherein producing electrode potential data further comprises recalculating the integral value of the electrode potential based on the changed cut-off voltage.

8. The charging control method as claimed in claim 7, wherein the correlation calculation further comprises:
recalculating the correlation between the recalculated integral value of the electrode potential and the lifespan data of the target battery; and
determining a final cut-off voltage by adjusting the cut-off voltage so that the recalculated correlation has linearity.

9. The charging control method as claimed in claim 8, wherein the predicting the lifespan of the target battery comprises predicting a remaining lifespan of the target battery over charge/discharge cycles based on a time of sudden drop.

10. The charging control method as claimed in claim 9, wherein the controlling a charging speed comprises mapping the charging speed and the predicted remaining lifespan of the target battery.

11. The charging control method as claimed in claim 10, wherein the controlling a charging speed further comprises controlling the charging speed of the target battery based on the mapping.

12. A charging control device of a battery comprising:
at least one processor configured to read out and execute instructions stored in at least one memory to thereby cause the charging control device to function as:
an electrode data production module configured to produce electrode potential data based on a current profile and a voltage profile of a target battery;
a lifespan analysis module configured to calculate a correlation between the electrode potential data and lifespan data of the target battery;
a lifespan prediction module configured to predict the lifespan of the target battery based on the correlation; and
a charging control module configured to control a charging speed of the target battery based on the predicted lifespan of the target battery.

13. The charging control device as claimed in claim 12, wherein the electrode data production module is configured to produce the electrode potential data by applying the current profile and the voltage profile to a physics-based model.

14. The charging control device as claimed in claim 13, wherein the electrode data production module is configured to calculate an integral value of the electrode potential based on a cut-off voltage of the target battery and the electrode potential data.

15. The charging control device as claimed in claim 14, wherein the lifespan analysis module is configured to calculate a correlation between the integral value of the electrode potential and a point in time when a charging capacity of the target battery suddenly drops.

16. The charging control device as claimed in claim 15, wherein the lifespan analysis module is configured to increase or decrease the cut-off voltage based on the calculated correlation.

17. The charging control device as claimed in claim 16, wherein the lifespan analysis module is configured to determine a final cut-off voltage by adjusting the cut-off voltage so that the correlation has linearity.

18. The charging control device as claimed in claim 17, wherein the lifespan prediction module is configured to predict a remaining lifespan of the target battery over charge/discharge cycles based on the point in time of sudden drop.

19. The charging control device as claimed in claim 18, wherein the charging control module is configured to map the charging speed and the predicted remaining lifespan of the target battery.

20. The charging control device as claimed in claim 19, wherein the charging control module is configured to control the charging speed of the target battery based on the map.
